(19) United States
(12) Patent Application Publication
(10) Pub. No.: US 2025/0038661 A1
(43) Pub. Date: Jan. 30, 2025

(54) SEMICONDUCTOR CIRCUIT DEVICE AND SWITCHING REGULATOR

(71) Applicant: SEIKO EPSON CORPORATION, Tokyo (JP)

(72) Inventor: Yuki Yamamoto, Chino-shi (JP)

(21) Appl. No.: 18/782,573

(22) Filed: Jul. 24, 2024

(30) Foreign Application Priority Data
Jul. 26, 2023 (JP) 2023-121449

(51) Int. Cl. H02M 3/156; H03F 1/32; H03F 3/45

(52) U.S. Cl. CPC H02M 3/156; H03F 1/3211; H03F 3/45183; H03F 2203/45091; H03F 2203/45344

(57) ABSTRACT

A semiconductor circuit device includes a differential amplifier circuit and a switching signal output circuit. The differential amplifier circuit outputs a current based on an output voltage of a switching regulator. The switching signal output circuit outputs a switching signal for a switching device based on a voltage at an output node of the differential amplifier circuit and a voltage corresponding to an inductor current flowing through an inductor. The differential amplifier circuit includes a first output-stage transistor and a second output-stage transistor. The first output-stage transistor is provided between a first power supply node and a first node and outputs the current. The second output-stage transistor is provided between the first node and the output node and has a gate to which a first bias voltage is input.

The present application is based on, and claims priority from JP Application Serial Number 2023-121449, filed Jul. 26, 2023, the disclosure of which is hereby incorporated by reference herein in its entirety.

### BACKGROUND

### 1. Technical Field

The present disclosure relates to a semiconductor circuit device, a switching regulator, and the like.

### 2. Related Art

US 2018/0152099 discloses a step-up current mode control switching regulator. The switching regulator includes an output voltage feedback circuit having a transconductance amplifier and a phase compensation circuit.

In the switching regulator, both the accuracy of an output voltage and the frequency characteristics of a feedback loop are desired to be achieved. The above-described US 2018/0152099 does not disclose a configuration in which both the accuracy of the output voltage and the frequency characteristics of the feedback loop are achieved.

### SUMMARY

An aspect of the present disclosure relates to a semiconductor circuit device that is used for a switching regulator that regulates an input voltage using a switching device and an inductor. The semiconductor circuit includes a differential amplifier circuit that outputs a current based on an output voltage of the switching regulator, and a switching signal output circuit that outputs a switching signal for the switching device based on a voltage at an output node of the differential amplifier circuit and a voltage corresponding to an inductor current flowing through the inductor. The differential amplifier circuit includes a first output-stage transistor that is provided between a first power supply node and a first node and outputs the current, and a second output-stage transistor that is provided between the first node and the output node and has a gate to which a first bias voltage is input.

Another aspect of the present disclosure relates to a switching regulator including the above-described semiconductor circuit device and the inductor.

### BRIEF DESCRIPTION OF THE DRAWINGS

FIG. 1 illustrates an example of a configuration of a switching regulator.

FIG. 2 is a diagram for explaining frequency characteristics of the switching regulator.

FIG. 3 is a diagram for explaining the frequency characteristics of the switching regulator.

FIG. 4 illustrates frequency characteristics when a DC gain is increased.

FIG. 5 illustrates a first example of a detailed configuration of a differential amplifier circuit.

FIG. 6 illustrates an example of frequency characteristics when the DC gain is increased by using the differential amplifier circuit according to the present embodiment.

FIG. 7 is a graph for explaining the relationship between output impedance and gain-frequency characteristics of the differential amplifier circuit.

FIG. 8 illustrates an example of a configuration of a semiconductor circuit device when a second example of the detailed configuration of the differential amplifier circuit is applied.

FIG. 9 illustrates the second example of the detailed configuration of the differential amplifier circuit.

FIG. 10 illustrates an example of a detailed configuration of a switching signal output circuit.

FIG. 11 illustrates an example of a waveform of a signal of the switching signal output circuit.

FIG. 12 illustrates an example of a detailed configuration of an inductance current detecting circuit.

FIG. 13 illustrates an example of a waveform of a signal of the inductance current detecting circuit.

FIG. 14 illustrates an example of a detailed configuration of a slope generating circuit.

### DESCRIPTION OF EMBODIMENTS

Hereinafter, preferred embodiments of the present disclosure will be described in detail. The present embodiment described below does not unduly limit the contents described in the appended claims, and all of configurations described in the present embodiment are not necessarily essential configuration requirements. For example, although a step-down switching regulator will be described below as an example, a method according to the present embodiment can also be used for a step-up switching regulator.

### 1. Switching Regulator and Semiconductor Circuit Device

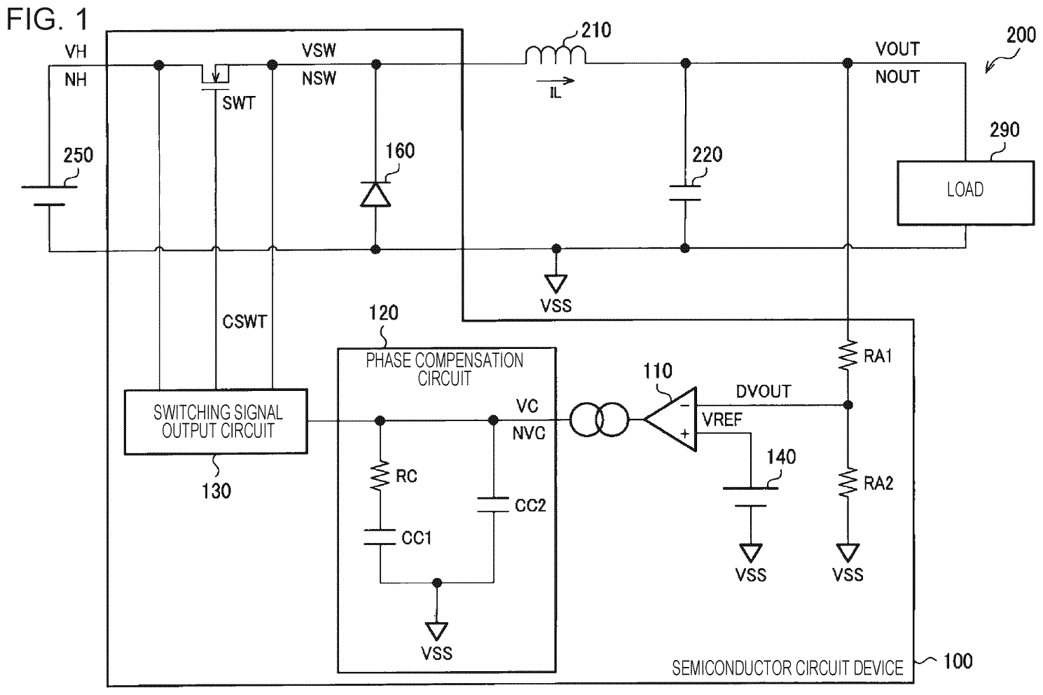

FIG. 1 illustrates an example of a configuration of a switching regulator. The switching regulator 200 includes a semiconductor circuit device 100, an inductor 210, and a capacitor 220.

A power supply 250 is coupled between a low-potential-side power supply node to which a low-potential-side power supply VSS is supplied and an input node NH of the switching regulator 200. The power supply 250 generates an input voltage VH to be applied to the switching regulator 200. The power supply 250 may be either an AC/DC converter or a DC/DC converter. In the present embodiment, coupling includes electrical coupling. The electrical coupling is coupling in which an electrical signal, a voltage, or a current can be transmitted, and includes coupling in which information can be transmitted by an electrical signal. The electrical coupling may be coupling via a passive element, an active element, or the like.

One end of the inductor 210 is coupled to a switching node NSW, and the other end of the inductor 210 is coupled to an output node NOUT of the switching regulator 200. One end of the capacitor 220 is coupled to the node NOUT, and the other end of the capacitor 220 is coupled to the low-potential-side power supply node. A current IL flowing through the inductor 210 is referred to as an inductor current.

A load 290 of the switching regulator 200 is provided between the output node NOUT and the low-potential-side power supply node. The load 290 is a circuit that uses an output voltage VOUT of the switching regulator 200 as a power supply voltage.

The semiconductor circuit device 100 controls the switching regulator 200 such that the output voltage VOUT of the switching regulator 200 becomes a predetermined voltage. The semiconductor circuit device 100 is an integrated circuit device in which a plurality of circuit elements are integrated on a semiconductor substrate. The semiconductor circuit device 100 includes a switching device SWT, a diode 160, a resistor RA1, a resistor RA2, a reference voltage generating circuit 140, a differential amplifier circuit 110, a phase compensation circuit 120, and a switching signal output circuit 130. The switching device SWT, the diode 160, the resistor RA1, the resistor RA2, and the reference voltage generating circuit 140 may be provided outside the semiconductor circuit device 100.

The switching device SWT is a transistor and is controlled to be turned on or off by a switching signal CSWT. Although FIG. 1 illustrates an example in which the switching device SWT is an N-type transistor, the switching device SWT may be a P-type transistor. The source of the switching device SWT is coupled to the switching node NSW, and the drain of the switching device SWT is coupled to the input node NH. The switching signal CSWT is input to the gate of the switching device SWT.

The anode of the diode 160 is coupled to the low-potential-side power supply node, and the cathode of the diode 160 is coupled to the switching node NSW. A switching device may be provided instead of the diode 160. The switching device is off when the switching device SWT is on. The switching device is on when the switching device SWT is off.

One end of the resistor RA1 is coupled to the output node NOUT, and the other end of the resistor RA1 is coupled to an inverting input terminal of the differential amplifier circuit 110. One end of the resistor RA2 is coupled to the inverting input terminal of the differential amplifier circuit 110, and the other end of the resistor RA2 is coupled to the low-potential-side power supply node. The resistors RA1 and RA2 divide the output voltage VOUT into a voltage DVOUT.

The reference voltage generating circuit 140 is coupled between a non-inverting input terminal of the differential amplifier circuit 110 and the low-potential-side power supply node. The reference voltage generating circuit 140 generates a reference voltage VREF for setting the voltage value of the output voltage VOUT. The semiconductor circuit device 100 performs feedback control to control the output voltage VOUT such that the voltage DVOUT becomes equal to the reference voltage VREF.

The differential amplifier circuit 110 converts the difference between the voltage DVOUT and the reference voltage VREF into a current, converts the current into a voltage VC by output impedance of the differential amplifier circuit 110, and outputs the voltage VC to an output node NVC. The differential amplifier circuit 110 is also referred to as a transconductance amplifier, a Gm amplifier, or an error amplifier.

The phase compensation circuit 120 is a circuit that performs phase compensation of a feedback loop. As will be described in detail later, a first pole and a second pole of the switching regulator 200 as a whole can be set based on the output impedance of the phase compensation circuit 120 and the differential amplifier circuit 110. Thus, the bandwidth and the phase margin of the switching regulator 200 can be controlled. The phase compensation circuit 120 includes a resistor RC, a first capacitor CC1, and a second capacitor CC2.

The resistor RC and the first capacitor CC1 are coupled in series between the output node NVC of the differential amplifier circuit 110 and the low-potential-side power supply node. One end of the resistor RC is coupled to the output node NVC, and the other end of the resistor RC is coupled to one end of the first capacitor CC1. The other end of the first capacitor CC1 is coupled to the low-potential-side power supply node. One end of the second capacitor CC2 is coupled to the output node NVC, and the other end of the second capacitor CC2 is coupled to the low-potential-side power supply node.

The switching signal output circuit 130 controls the on-duty of the switching device SWT based on the voltage VC at the output node NVC of the differential amplifier circuit 110 and the inductor current IL. That is, the switching signal output circuit 130 controls a pulse width of the switching signal CSWT, which is a PWM signal, based on the voltage VC and the inductor current IL. PWM is an abbreviation for Pulse Width Modulation. The inductor current IL is converted into a voltage by the on-resistance of the switching device SWT. The switching signal output circuit 130 obtains the voltage based on the difference in potential between both ends of the switching device SWT and performs PWM control based on the difference in potential. The voltage based on the current flowing through the inductor 210 is not limited to the difference in potential between both ends of the switching device SWT, and may be, for example, the difference in potential between both ends of a sense resistor coupled in series to the inductor 210. The switching signal output circuit 130 may perform not only the PWM control but also PFM control, for example. That is, the switching signal output circuit 130 may control a pulse frequency of the switching signal CSWT, which is a PFM signal, based on the voltage VC and the inductor current IL. PFM is an abbreviation for Pulse Frequency Modulation.

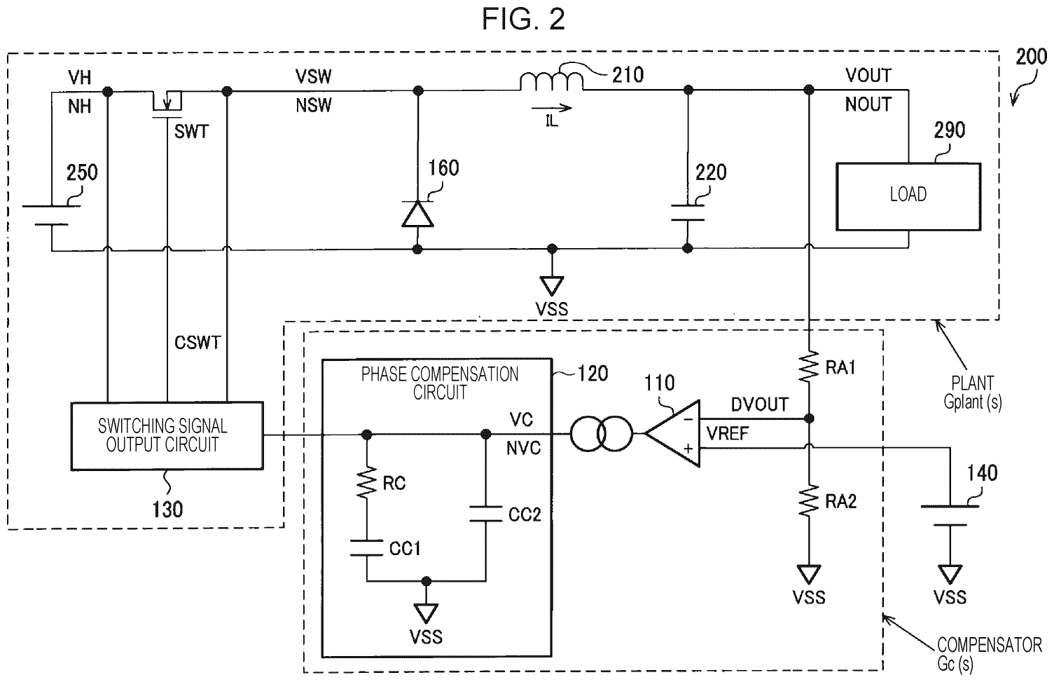

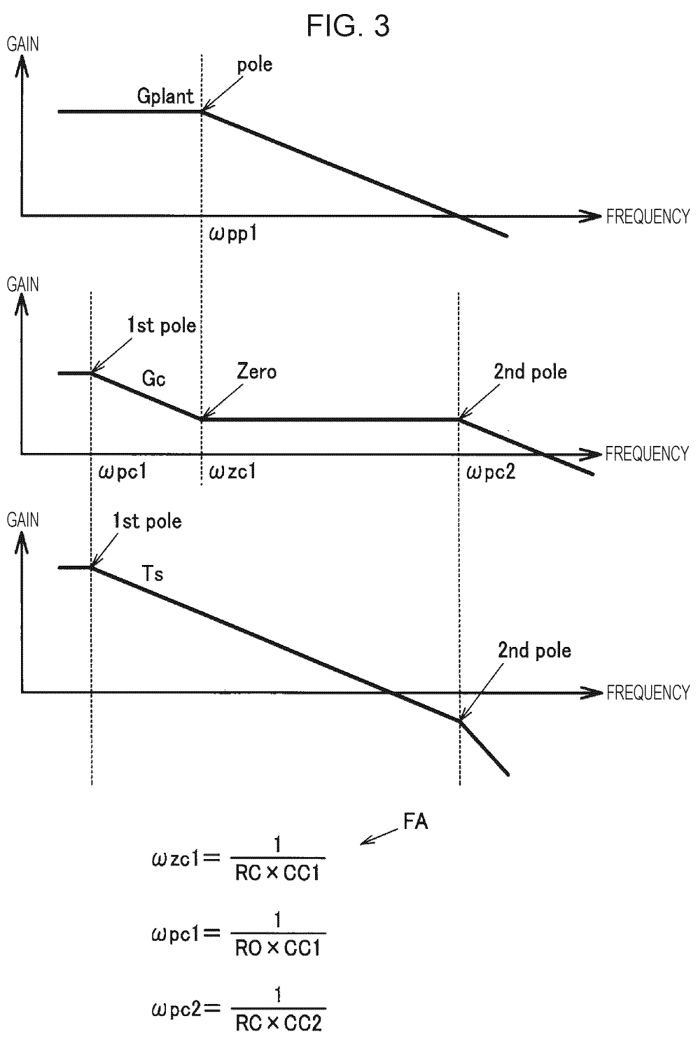

FIGS. 2 and 3 are diagrams illustrating the frequency characteristics of the switching regulator.

As illustrated in FIG. 2, the switching regulator 200 is divided into a plant and a compensator. The compensator includes a resistor RA1, a resistor RA2, a differential amplifier circuit 110, and a phase compensation circuit 120. The other components that are included in the switching regulator 200 and exclude the compensator are the plant. A transfer function of the plant is Gplant, and a transfer function of the compensator is Gc.

FIG. 3 illustrates the frequency characteristics of the gain of the transfer function.

The transfer function Gplant of the plant illustrated in an upper diagram in FIG. 3 has a pole at a frequency ωpp1. The frequency ωpp1 is determined based on a circuit constant of a circuit constituting the plant. The transfer function Gc of the compensator illustrated in a middle diagram in FIG. 3 has a first pole at a frequency ωpc1, a zero point at a frequency ωzc1, and a second pole at a frequency ωpc2. As indicated by Equations FA, the frequency ωzc1 of the zero point is set based on the resistor RC and the first capacitor CC1 of the phase compensation circuit 120. The frequency ωpc1 of the first pole is set based on the output impedance RO of the differential amplifier circuit 110 and the first capacitor CC1 of the phase compensation circuit 120. The frequency ωpc2 of the second pole is set based on the resistor RC and the second capacitor CC2 of the phase compensation circuit 120. These frequencies satisfy ωpc1<ωzc1<ωpc2.

The frequency ωzc1 of the zero point of the compensator is set to be substantially equal to the frequency ωpp1 of the pole of the plant. That is, the resistance value of the resistor RC and the capacitance value of the first capacitor CC1 are set such that the frequency ωzc1 is substantially equal to the frequency ωpp1. As a result, as illustrated in a lower diagram in FIG. 3, the pole of the plant and the zero point of the compensator cancel each other in the transfer function Ts of the switching regulator 200 as a whole. That is, the transfer function Ts has the first pole at the frequency ωpc1 and the second pole at the frequency ωpc2. The frequencies of these poles are controlled by the compensator. Therefore, the bandwidth, the phase margin, and the like of the switching regulator 200 can be controlled by determining a circuit constant of the compensator.

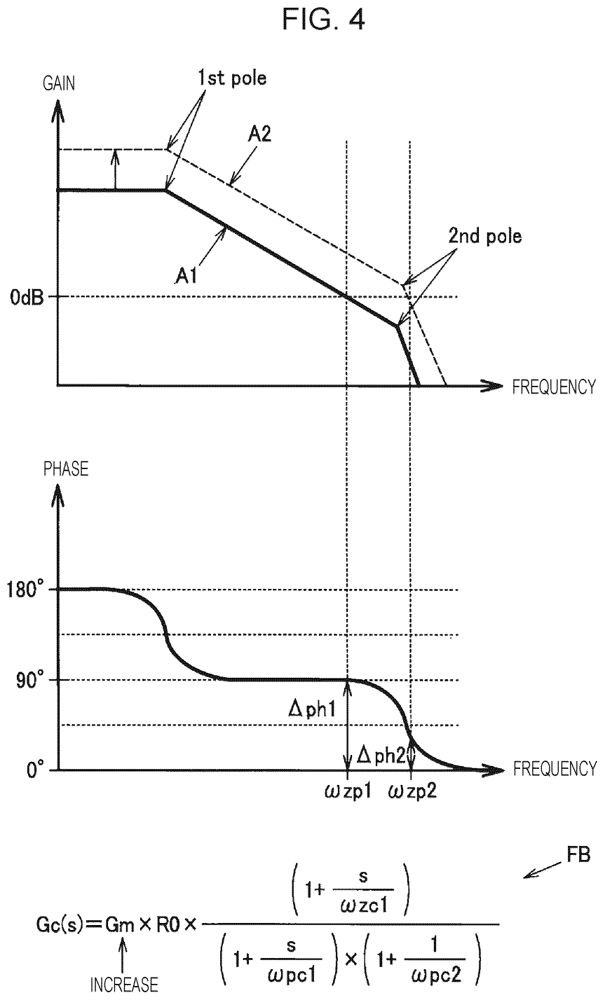

FIG. 4 illustrates an example of frequency characteristics when a DC gain is increased.

In the switching regulator 200, the higher the DC gain of the transfer function Ts is, the higher the accuracy of the output voltage VOUT is. For example, when the impedance of the load 290 changes, the output voltage VOUT may fluctuate. By increasing the DC gain of the transfer function Ts, the fluctuation of the output voltage VOUT can be reduced. Therefore, it is desirable that the DC gain of the transfer function Ts of the switching regulator 200 as a whole be high.

In this case, it is assumed that the DC gain of the transfer function Ts is increased by increasing the DC gain of the differential amplifier circuit 110. The DC gain of the differential amplifier circuit 110 is Gm×RO. As indicated by Equation FB in FIG. 4, when the DC gain Gm×RO is increased, the DC gain of the transfer function Gc of the compensator increases, and as a result, the gain of the transfer function Ts of the switching regulator 200 as a whole increases.

Gm of the DC gain Gm×RO is the transconductance of the differential amplifier circuit 110. The differential amplifier circuit 110 converts a differential input voltage VREF−DVOUT into a current. When the current is represented by IC, Gm=IC/(VREF−DVOUT). RO is the output impedance of the differential amplifier circuit 110, and RO=IC/VC.

FIG. 4 illustrates a change in the transfer function Ts when Gm of the DC gain Gm×RO is increased. A line A1 illustrated in an upper diagram FIG. 4 indicates the gain-frequency characteristics before Gm increases, and a line A2 indicates the gain-frequency characteristics after Gm increases. Since the frequencies ωpc1 and ωpc2 of the poles and the frequency ωzc1 of the zero point described with reference to FIG. 3 are not affected by Gm, the positions of the poles on the line A1 and the line A2 do not change, and the gain increases at all frequencies as illustrated in the upper diagram in FIG. 4. Further, as illustrated in a lower diagram in FIG. 4, the phase-frequency characteristics do not change before and after Gm increases. In this case, since the gain increases at all the frequencies, zero-crossing frequencies at which the gain is 0 dB increase. When the zero-crossing frequencies of the lines A1 and A2 are represented by ωzp1 and ωzp2, respectively, ωzp1<ωzp2. Since the phase-frequency characteristics do not change before and after Gm increases, a phase margin Δph2 at the zero-crossing frequency ωzp2 is smaller than a phase margin Δzp1 at the zero-crossing frequency ωzp1. That is, when the DC gain of the transfer function Ts is increased by increasing Gm, the DC gain can be increased, but the feedback loop becomes unstable.

### 2. Differential Amplifier Circuit

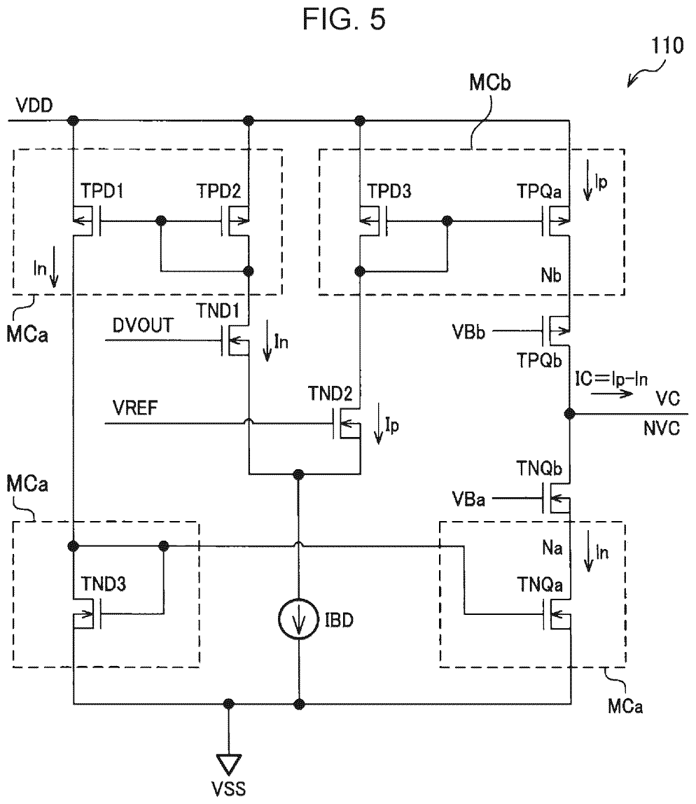

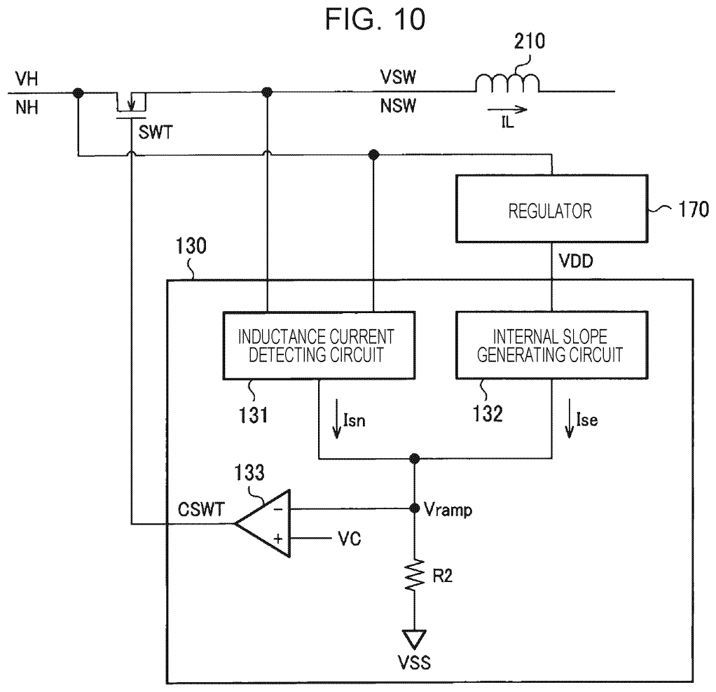

FIG. 5 illustrates a first example of a detailed configuration of the differential amplifier circuit according to the present embodiment. The differential amplifier circuit 110 includes a first differential pair transistor TND1, a second differential pair transistor TND2, output-stage transistors TNQa, TNQb, TPQa, and TPQb, P-type transistors TPD1 to TPD3, an N-type transistor TND3, and a current source circuit IBD. The power supply voltage of the differential amplifier circuit 110 is an internal power supply voltage VDD generated by the regulator 170 described later with reference to FIG. 10.

The first differential pair transistor TND1 and the second differential pair transistor TND2 are N-type transistors and constitute a differential pair. The voltage DVOUT is input to the gate of the first differential pair transistor TND1, and the reference voltage VREF is input to the gate of the second differential pair transistor TND2. The current source circuit IBD supplies a current to the differential pair. A current flowing through the first differential pair transistor TND1 is represented by In, and a current flowing through the second differential pair transistor TND2 is represented by Ip.

As indicated by a broken line in FIG. 5, the differential amplifier circuit 110 includes current mirror circuits MCa and MCb. The current mirror circuit MCa mirrors the current In as a current flowing through the output-stage transistor TNQa. The current mirror circuit MCa includes the P-type transistors TPD1 and TPD2, and the N-type transistor TND3.

The current In flows through the P-type transistor TPD2. The P-type transistors TPD1 and TPD2 constitute a current mirror, and the current In flows through the P-type transistor TPD1. The current In flows through the N-type transistor TND3. The N-type transistor TND3 and the output-stage transistor TNQa constitute a current mirror, and the current In flows through the output-stage transistor TNQa.

The current mirror circuit MCb mirrors the current Ip as a current flowing through the output-stage transistor TPQa. The current mirror circuit MCb includes the P-type transistor TPD3.

The current Ip flows through the P-type transistor TPD3. The P-type transistor TPD3 and the output-stage transistor TPQa constitute a current mirror, and the current Ip flows through the output-stage transistor TPQa.

The output-stage transistors TNQa and TNQb are N-type transistors. The output-stage transistor TNQa is provided between the low-potential-side power supply node and a node Na. The output-stage transistor TNQb is provided between the node Na and the output node NVC. The coupling of the output-stage transistors TNQa and TNQb may be referred to as so-called cascode-coupling.

A bias voltage VBa is input to the gate of the output-stage transistor TNQb. For example, a voltage generating circuit (not illustrated) generates the bias voltage VBa. When a threshold voltage of each of the N-type transistors is set to Vthn, the bias voltage is VBa=Vthn+2×Vovn. Vovn is an overdrive voltage of each of the N-type transistors. The overdrive voltage is applied between the source and the drain of the transistor and is necessary for operating the transistor in a saturation region. Since VBa=Vthn+2×Vovn, the output-stage transistors TNQa and TNQb operate in a saturation region in a state in which VC≥2×Vovn. For example, Vovn is about 0.2 V.

The output-stage transistors TPQa and TPQb are P-type transistors. The output-stage transistor TPQa is provided between a high-potential-side power supply node and a node Nb. The output-stage transistor TPQb is provided between the node Nb and the output node NVC. The coupling of the output-stage transistors TPQa and TPQb may be referred to as so-called cascode-coupling.

A bias voltage VBb is input to the gate of the output-stage transistor TNQb. For example, a voltage generating circuit (not illustrated) generates the bias voltage VBb. When a threshold voltage of each of the P-type transistors is Vthp, the bias voltage is VBb=Vthp+2×Vovp. Vovp is an overdrive voltage of each of the P-type transistors. Since VBb=Vthp+2×Vovp, the output-stage transistors TPQa and TPQb operate in a saturation region in a state in which VC≤VDD−2×Vovp. For example, Vovp is about 0.2 V.

The differential amplifier circuit 110 may include a resistor provided between the node Na and the output node NVC instead of the output-stage transistor TNQb. The differential amplifier circuit 110 may include a resistor provided between the node Nb and the output node NVC instead of the output-stage transistor TPQb.

The differential amplifier circuit 110 outputs a differential current IC=Ip−In that is the difference between the current Ip flowing through the output-stage transistors TPQa and TPQb and the current In flowing through the output-stage transistors TNQa and TNQb. The differential current IC=Ip−In is converted into the voltage VC by the output impedance RO of the differential amplifier circuit 110. That is, VC=IC×RO.

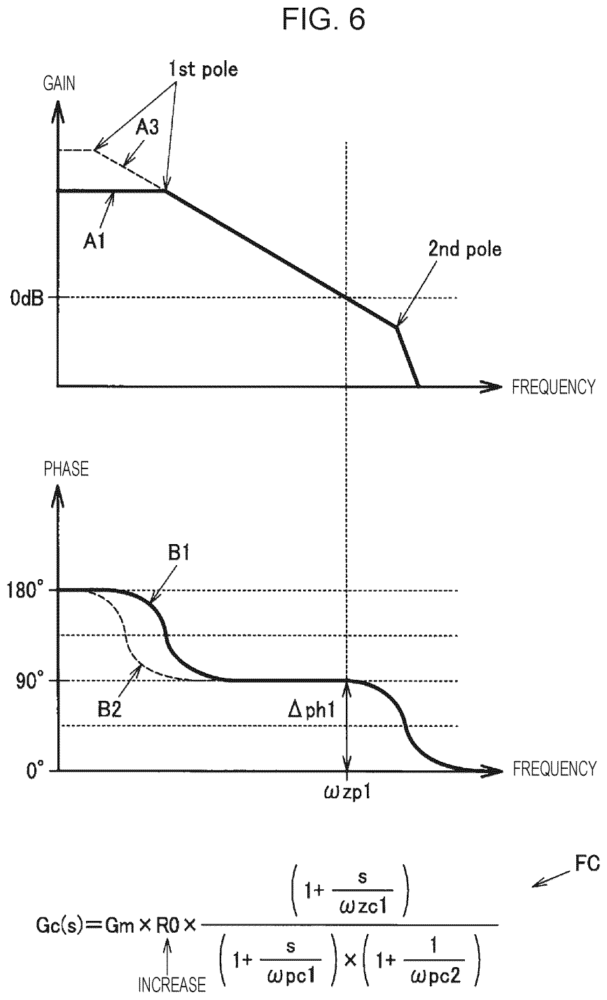

FIG. 6 illustrates an example of frequency characteristics when the DC gain is increased using the differential amplifier circuit according to the present embodiment.

As described with reference to FIG. 5, the output-stage transistors of the differential amplifier circuit 110 are cascode-coupled. As a result, as indicated by Equation FC in FIG. 6, the output impedance RO of the DC gain Gm×RO of the compensator increases. As described above, the frequency ωpc1 of the first pole is 1/(RO×CC1). Thus, the frequency ωpc1 decreases as the output impedance RO increases. Therefore, as indicated by a line A3 in an upper diagram in FIG. 6, the DC gain of the transfer function Ts increases due to the increase in RO. However, the line A3 becomes the same as the line A1 at frequencies higher than the frequency ωpc1 of the first pole because the frequency ωpc1 of the first pole decreases. Therefore, zero-crossing frequencies of the lines A1 and A3 are the same frequency ωzp1.

As illustrated in a lower part of FIG. 6, a line B1 indicates phase-frequency characteristics corresponding to the line A1 for the gain, and a line B2 indicates phase-frequency characteristics corresponding to the line A3 for the gain. Since the zero-crossing frequencies do not change even when RO increases, the phase margin Δph1 also does not change. That is, by using the differential amplifier circuit 110 according to the present embodiment, the DC gain of the feedback loop can be increased and the feedback loop can be kept stable.

The transconductance Gm of the differential amplifier circuit 110 can be relatively easily increased by, for example, increasing the mirror ratio of each of the current mirror circuits. Meanwhile, it is necessary to change the channel length L of the W/L dimension of each of the output-stage transistors in order to increase the output impedance RO, and there is an upper limit to the increase in RO. According to the present embodiment, it is possible to greatly increase RO by cascode-coupling the output-stage transistors. In addition, since only the output-stage transistors that are cascode-coupled are provided, an effect on the layout area is small.

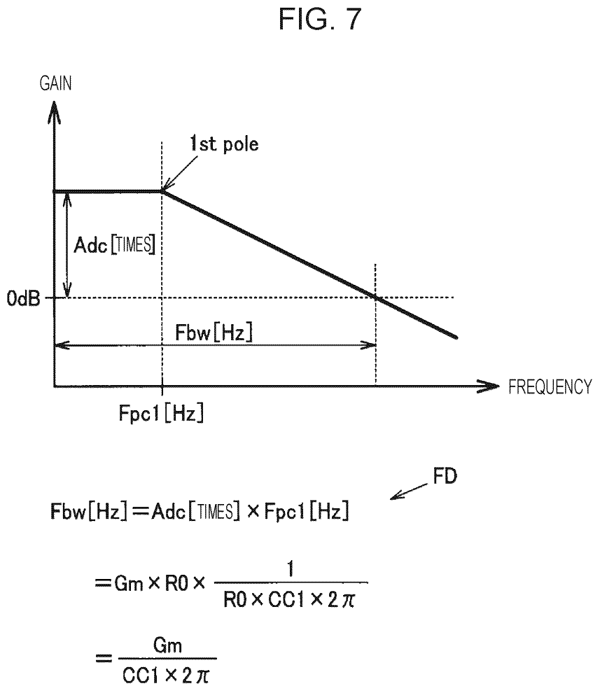

FIG. 7 is a diagram for explaining the relationship between the output impedance and gain-frequency characteristics of the differential amplifier circuit.

The DC gain is represented by Adc [times], the bandwidth is represented by Fbw [Hz], and the frequency of the first pole is represented by Fpc1 [Hz]. The unit [times] of Adc means how many times the gain is based on 1 time which is 0 dB.

As indicated by Equation FD, the bandwidth Fbw is proportional to the transconductance Gm, but is not affected by the output impedance RO. When the DC gain Adc is increased by increasing the transconductance Gm, there is a possibility that the bandwidth Fbw may be widened and the loop may become unstable. On the other hand, when the DC gain Adc is increased by increasing the output impedance RO, the bandwidth Fbw does not change, and thus the stability of the loop is not affected.

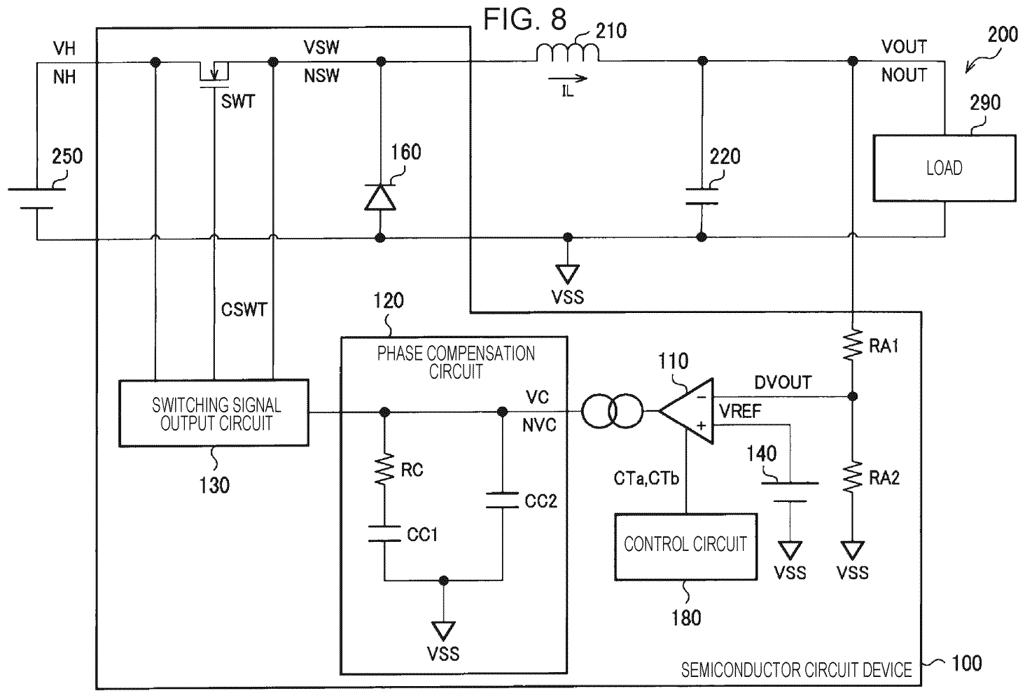

A second example of the detailed configuration of the differential amplifier circuit 110 will be described. FIG. 8 illustrates an example of a configuration of the semiconductor circuit device when the second example of the detailed configuration of the differential amplifier circuit is applied. Differences from FIG. 1 will be mainly described below.

The semiconductor circuit device 100 includes a control circuit 180. As will be described later, the differential amplifier circuit 110 includes a switch. The control circuit 180 outputs control signals CTa and CTb for controlling the switch to turn on or off the switch. The control circuit 180 outputs a control signal for turning on the switch or a control signal for turning off the switch based on, for example, register setting.

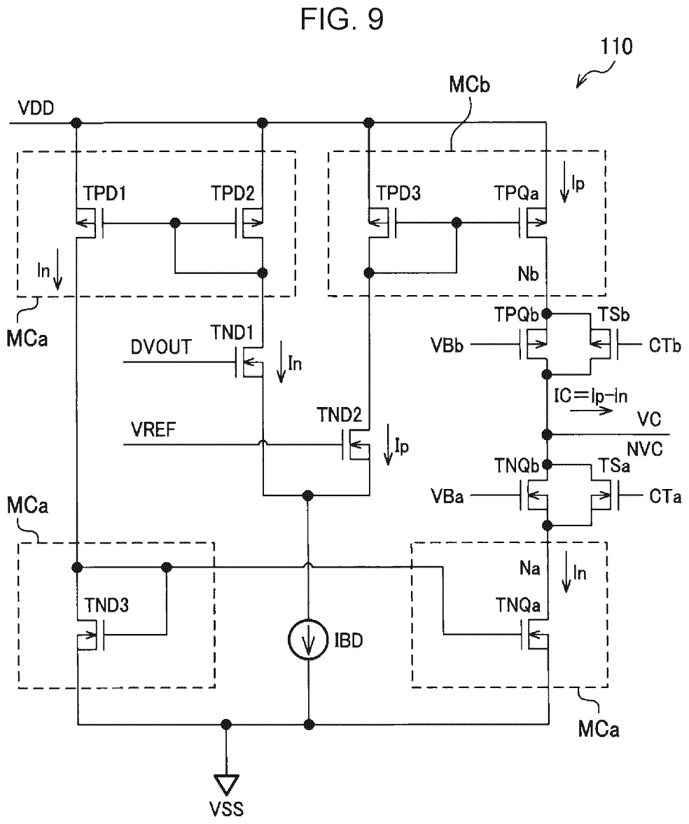

FIG. 9 illustrates the second example of the detailed configuration of the differential amplifier circuit. Differences from FIG. 5 will be mainly described below. The differential amplifier circuit 110 includes switches TSa and TSb.

The switch TSa is provided between the node Na and the output node NVC. The switch TSa is an N-type transistor, and the control signal CTa is input to the gate of the switch TSa. The switch TSb is provided between the node Nb and the output node NVC. The switch TSb is a P-type transistor, and the control signal CTb is input to the gate of the switch TSb. In this configuration example, the cascode-coupling of the output-stage transistors can be released. That is, when the switches TSa and TSb are turned on, both ends of the output-stage transistor TNQb and the source and the drain of the output-stage transistor TPQb are short-circuited, and the cascode-coupling of the output-stage transistors is released. When the switches TSa and TSb are turned off, the output-stage transistors are cascode-connected.

In the present embodiment, the semiconductor circuit device 100 is used for the switching regulator 200. The switching regulator 200 regulates the input voltage VH using the switching device SWT and the inductor 210. The semiconductor circuit device 100 includes the differential amplifier circuit 110 and the switching signal output circuit 130. The differential amplifier circuit 110 outputs the current IC based on the output voltage VOUT of the switching regulator 200. The switching signal output circuit 130 outputs the switching signal CSWT for the switching device SWT based on the voltage VC at the output node NVC of the differential amplifier circuit 110 and a voltage corresponding to the inductor current IL flowing through the inductor 210. The differential amplifier circuit 110 includes a first output-stage transistor and a second output-stage transistor. The first output-stage transistor is provided between a first power supply node and a first node and outputs the current. The second output-stage transistor is provided between the first node and the output node and has a gate to which a first bias voltage is input.

According to the present embodiment, since the first output-stage transistor and the second output-stage transistor are cascode-connected, the output impedance RO of the differential amplifier circuit 110 increases. As described with reference to FIG. 6 and the like, since the output impedance RO increases, the DC gain of the transfer function Ts of the switching regulator 200 increases, and thus the accuracy of the output voltage VOUT is improved. Since the phase margin Δph1 of the feedback loop is not affected, the feedback loop is kept stable. In this way, it is possible to achieve the accuracy of the output voltage and the frequency characteristics of the feedback loop.

The first output-stage transistor may be either the transistor TNQa or the transistor TPQa illustrated in FIG. 5. When the transistor TNQa is the first output-stage transistor, the transistor TNQb is the second output-stage transistor, the low-potential-side power supply node is the first power supply node, the node Na is the first node, and the bias voltage VBa is the first bias voltage. When the transistor TPQa is the first output-stage transistor, the transistor TPQb is the second output-stage transistor, the high-potential-side power supply node is the first power supply node, the node Nb is the first node, and the bias voltage VBb is the first bias voltage.

Further, in the present embodiment, the differential amplifier circuit 110 may include the first differential pair transistor TND1, the second differential pair transistor TND2, and a current mirror circuit. The voltage DVOUT based on the output voltage VOUT output from the switching regulator 200 may be input to the gate of the first differential pair transistor TND1. The reference voltage VREF may be input to the gate of the second differential pair transistor TND2. The current mirror circuit may mirror a current flowing through one of the first differential pair transistor TND1 and the second differential pair transistor TND2 as a current flowing through the first output-stage transistor.

According to the present embodiment, a current flows through the differential pair transistors in accordance with a voltage input to the gates of the differential pair transistors, and the current is mirrored to the output-stage transistors. Thus, the differential amplifier circuit 110 outputs a current corresponding to the input voltage. That is, the differential amplifier circuit 110 functions as a transconductance amplifier.

When the transistor TNQa is the first output-stage transistor, the current mirror circuit MCa is the above-described current mirror circuit. The current mirror circuit MCa mirrors the current In flowing through the first differential pair transistor TND1 as a current flowing through the output-stage transistor TNQa. When the transistor TPQa is the first output-stage transistor, the current mirror circuit MCb is the above-described current mirror circuit. The current mirror circuit MCb mirrors the current Ip flowing through the second differential pair transistor TND2 as a current flowing through the output-stage transistor TPQa.

In the present embodiment, the differential amplifier circuit 110 may include a third output-stage transistor and a fourth output-stage transistor. The third output-stage transistor may be provided between a second node and a second power supply node at a potential different from a potential of the first power supply node and may output a current. The fourth output-stage transistor may be provided between the second node and the output node and have a gate to which a second bias voltage is input.

According to the present embodiment, the output-stage transistors are cascode-connected on both the first power supply node side and the second power supply node side. The differential amplifier circuit 110 outputs the difference between a current flowing through the output-stage transistors on the first power supply node side and a current flowing through the output-stage transistors on the second power supply node side. In the present embodiment, since the impedance is high with respect to the current on each of the power supply node sides, the output impedance RO of the differential amplifier circuit 110 is high.

When the transistor TNQa is the first output-stage transistor, the transistor TPQa is the third output-stage transistor, the transistor TPQb is the fourth output-stage transistor, the high-potential-side power supply node is the second power supply node, the node Nb is the second node, and the bias voltage VBb is the second bias voltage. When the transistor TPQa is the first output-stage transistor, the transistor TNQa is the third output-stage transistor, the transistor TNQb is the fourth output-stage transistor, the low-potential-side power supply node is the second power supply node, the node Na is the second node, and the bias voltage Vba is the second bias voltage.

In addition, in the present embodiment, the differential amplifier circuit 110 may include the first differential pair transistor TND1, the second differential pair transistor TND2, a first current mirror circuit, and a second current mirror circuit. The first current mirror circuit may mirror a current flowing through one of the first differential pair transistor TND1 and the second differential pair transistor TND2 as a current flowing through the first output-stage transistor. The second current mirror circuit may mirror a current flowing through the other of the first differential pair transistor TND1 and the second differential pair transistor TND2 as a current flowing through the third output-stage transistor.

According to the present embodiment, the difference between the current In corresponding to the voltage DVOUT input to the gate of the first differential pair transistor TND1 and the current Ip corresponding to the reference voltage VREF input to the gate of the differential pair transistor TND2 is output to the output node NVC of the differential amplifier circuit 110. Therefore, the differential amplifier circuit 110 outputs a current corresponding to the difference between the two input voltages. That is, the differential amplifier circuit 110 functions as a transconductance amplifier.

When the transistor TNQa is the first output-stage transistor, the current mirror circuit MCa is the first current mirror circuit, and the current mirror circuit MCb is the second current mirror circuit. When the transistor TPQa is the first output-stage transistor, the current mirror circuit MCb is the first current mirror circuit, and the current mirror circuit MCa is the second current mirror circuit.

Further, in the present embodiment, the first output-stage transistor and the second output-stage transistor may be MOS transistors. A size of the second output-stage transistor may be identical to a size of the first output-stage transistor.

Similarly, the third output-stage transistor and the fourth output-stage transistor may be MOS transistors. A size of the fourth output-stage transistor may be identical to the size of the second output-stage transistor.

According to the present embodiment, overdrive voltages of two cascode-coupled output-stage transistors can be regarded as the same. Thus, the setting of the bias voltages is simplified. As described above, for example, the bias voltages can be set to VBa=Vthn+2×Vovn and VBb=Vthp+2×Vovp.

In this embodiment, the first power supply node may be the low-potential-side power supply node. The second power supply node may be the high-potential-side power supply node. The first output-stage transistor and the second output-stage transistor may be N-type MOS transistors. The third output-stage transistor and the fourth output-stage transistor may be P-type MOS transistors.

In this case, the first output-stage transistor is the transistor TNQa, the second output-stage transistor is the transistor TNQb, the third output-stage transistor is the transistor TPQa, and the fourth output-stage transistor is the transistor TPQb.

In addition, in the present embodiment, the output impedance of the first output-stage transistor and the second output-stage transistor may be 1 MΩ or greater.

In addition, in the present embodiment, the output impedance of the first to fourth output-stage transistors may be 1 MΩ or greater.

According to the present embodiment, a sufficiently large gain can be obtained as the DC gain of the switching regulator 200 as a whole. For example, it is possible to obtain sufficiently large output impedance RO, that is, a sufficiently large DC gain, compared to the DC gain when the channel length L of each of the output-stage transistors is changed in a state in which the output-stage transistors are not cascode-coupled.

In the present embodiment, the semiconductor circuit device 100 may include the control circuit 180. The differential amplifier circuit 110 may include a first switch coupled in parallel to the second output-stage transistor. The control circuit 180 may control the first switch such that the first switch is turned on or off.

In the present embodiment, the semiconductor circuit device 100 may include the control circuit 180. The differential amplifier circuit 110 may include a first switch coupled in parallel to the second output-stage transistor and a second switch coupled in parallel to the fourth output-stage transistor. The control circuit 180 may control the first switch and the second switch such that the first switch and the second switch are turned on or off.

According to the present embodiment, when the first switch is turned off, the second output-stage transistor is cascode-coupled to the first output-stage transistor. When the first switch is turned on, both ends of the second output-stage transistor are short-circuited. When the second switch is turned off, the fourth output-stage transistor is cascode-coupled to the third output-stage transistor. When the second switch is turned on, both ends of the fourth output-stage transistor are short-circuited. In this way, the cascode-coupling can be enabled or disabled.

When the transistor TNQb is the second output-stage transistor, the switch TSa is the first switch, the transistor TPb is the fourth output-stage transistor, and the switch TSb is the second switch. When the transistor TPQb is the second output-stage transistor, the switch TSb is the first switch, the transistor TPa is the fourth output-stage transistor, and the switch TSa is the second switch.

### 3. Switching Signal Output Circuit

FIG. 10 illustrates an example of a detailed configuration of the switching signal output circuit. The semiconductor circuit device 100 includes the regulator 170. The switching signal output circuit 130 includes an inductance current detecting circuit 131, an internal slope generating circuit 132, a comparing circuit 133, and a resistor R2.

The regulator 170 is a DC/DC converter that regulates the input voltage VH to the internal power supply voltage VDD. The regulator 170 is, for example, a linear regulator including an operational amplifier and a resistor, but is not limited thereto.

The inductance current detecting circuit 131 detects the inductor current IL based on the difference between the input voltage VH and the voltage VSW at the switching node NSW and outputs the result of the detection as a detected current Isn.

The internal slope generating circuit 132 operates with the internal power supply voltage VDD and generates a slope current Ise having a predetermined slope.

One end of the resistor R2 is coupled to an output node of the inductance current detecting circuit 131, an output node of the internal slope generating circuit 132, and an inverting input node of the comparing circuit 133. The other end of the resistor R2 is coupled to the low-potential-side power supply node. The resistor R2 converts the detected current Isn and the slope current Ise into the voltage Vramp.

The voltage VC is input from the differential amplifier circuit 110 to a non-inverting input terminal of the comparing circuit 133. The comparing circuit 133 compares the voltage Vramp with the voltage VC and generates a switching signal CSWT which is a PWM signal.

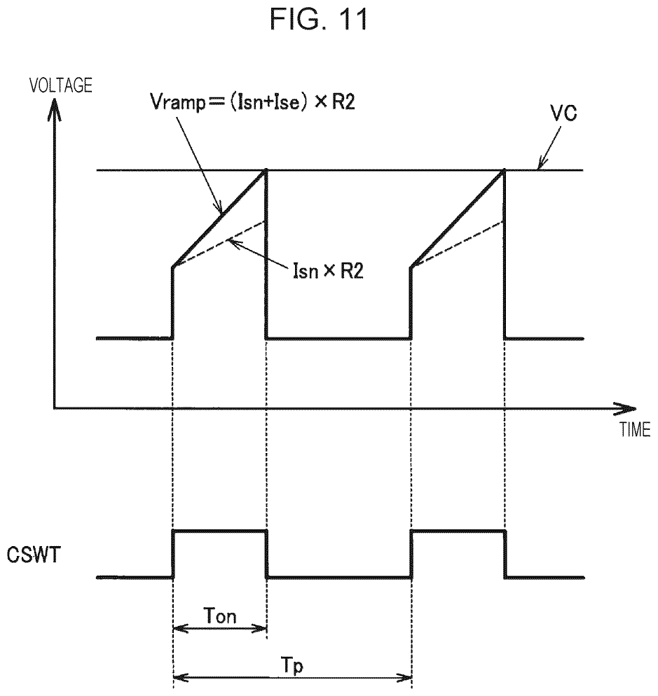

FIG. 11 illustrates an example of a waveform of a signal of the switching signal output circuit.

The comparing circuit 133 performs the comparison operation when the voltage Vramp is lower than the voltage VC at a comparison timing in each period Tp, and does not perform the comparison operation when the voltage Vramp is equal to or higher than the voltage VC at the comparison timing in each period Tp. That is, the comparing circuit 133 resets the switching signal CSWT to a high level when the voltage Vramp is lower than the voltage VC at each comparison timing. When the switching signal CSWT is reset to the high level, the switching device SWT is switched from off to on, and the detected current Isn and the slope current Ise are output. In this case, Vramp=(Isn+Ise)×R2. When the voltage Vramp reaches the voltage VC, the comparing circuit 133 changes the switching signal CSWT from the high level to a low level. As a result, the switching device SWT is switched from on to off. When the switching device SWT is turned off, the detected current Isn and the slope current Ise are not output. Each comparison timing is determined based on, for example, a clock signal generated by an internal oscillation circuit (not illustrated). However, each comparison timing may be determined based on a clock signal supplied from the outside of the semiconductor circuit device 100, or may be determined using a counter or the like.

Although FIG. 11 illustrates the voltage VC as a constant voltage, the voltage VC is actually affected by the output voltage VOUT. When the load of the switching regulator 200 is large, the output voltage VOUT quickly decreases after the switching device SWT is turned off. Therefore, the voltage VC is maintained at a relatively high voltage, and the time required to return to Vramp<VC is shorter than the period Tp. Therefore, at each comparison timing, Vramp<VC is established and the comparison operation is performed. In this case, the control of the switching device SWT is the PWM control.

On the other hand, when the load of the switching regulator 200 is small, it takes time for the output voltage VOUT to decrease after the switching device SWT is turned off. Therefore, the voltage VC becomes a relatively low voltage, and the time required to return to Vramp<VC is longer than the period Tp. Therefore, after the switching device SWT is turned on and off, Vramp<VC is established after one or more periods Tp, and the comparison operation is performed. In this case, the control of the switching device SWT is the PFM control.

FIG. 11 illustrates an example of the PWM control. As described above, the voltage VC fluctuates in a short time period, but the voltage VC as an average for a long time period is controlled such that the voltage DVOUT obtained by dividing the output voltage VOUT matches the reference voltage VREF. When the voltage VC changes, a time period Ton for which the switching device SWT is on changes, the on-duty of the switching signal CSWT, which is a PWM signal, changes, and the output voltage VOUT changes. In this way, the feedback control is performed such that the output voltage VOUT as the average for the long time period is kept constant.

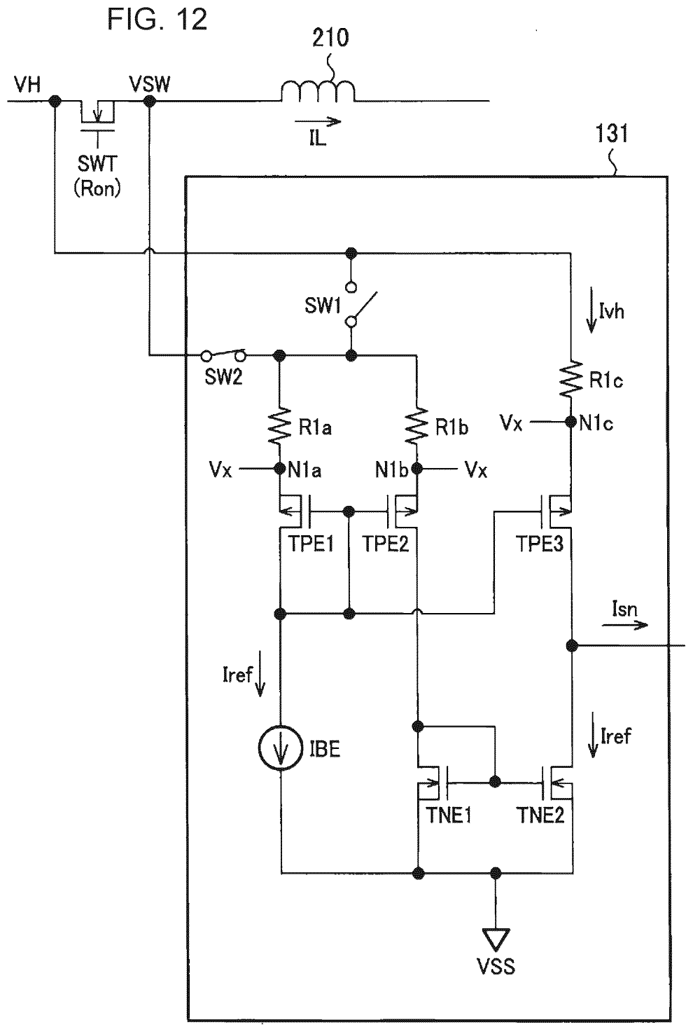

FIG. 12 illustrates an example of a detailed configuration of the inductance current detecting circuit. The inductance current detecting circuit 131 includes switches SW1 and SW2, resistors R1a, R1b, and R1c, P-type transistors TPE1, TPE2, and TPE3, N-type transistors TNE1 and TNE2, and a current source circuit IBE. An operation of the inductance current detecting circuit 131 is described below using an example of waveforms of signals.

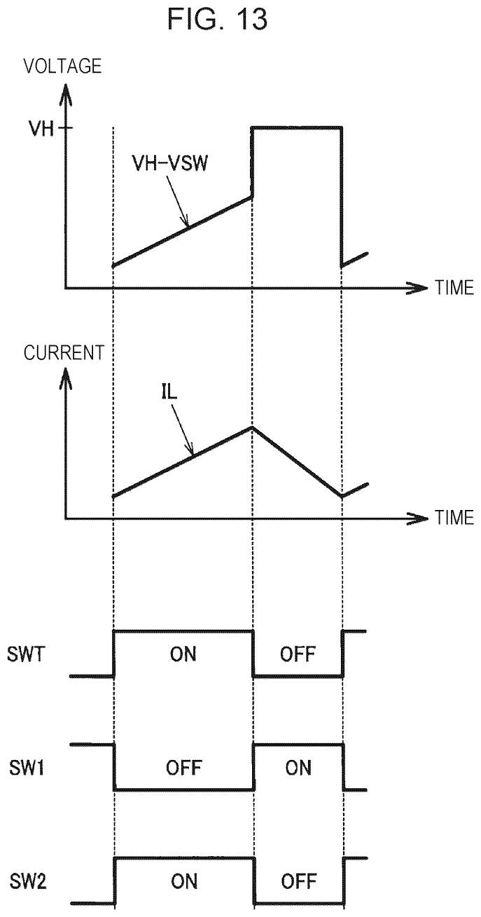

FIG. 13 illustrates an example of waveforms of signals of the inductance current detecting circuit. The on-resistance of the switching device SWT is represented by Ron. It is assumed that resistance values of the resistors R1a, R1b, and R1c are equal and are R1.

As illustrated in FIG. 13, when the switching device SWT is on, the switch SW1 is off and the switch SW2 is on. The inductor current IL gradually increases. The inductor current IL is converted into the difference in potential expressed in Equation (1) below by the on-resistance Ron. The inductance current detecting circuit 131 generates the detected current Isn from the difference VH−VSW in potential.

$$VH - VSW = IL \times Ron \qquad ( 1 )$$

Specifically, the current source circuit IBE causes a current Iref to flow through the resistor R1a and the P-type transistor TPE1. A voltage at a node N1a between the resistor R1a and the P-type transistor TPE1 is represented by Vx. Since the difference in potential between both ends of the resistor R1a is VSW−Vx, the current Iref is expressed by Equation (2) below.

$$Iref = ( VSW - Vx ) / R 1 \qquad ( 2 )$$

The P-type transistors TPE1 and TPE2 constitute a current mirror, and the current Iref flows through the resistor R1b and the P-type transistor TPE2. The P-type transistors TPE1 and TPE3 constitute a current mirror, and the current Iref flows through the resistor R1c and the P-type transistor TPE3. As a result, a voltage at a node N1b between the resistor R1b and the P-type transistor TPE2 and a voltage at a node N1c between the resistor R1c and the P-type transistor TPE3 become equal to Vx.

Since the difference in potential between both ends of the resistor R1c is VH−Vx, a current Ivh flowing through the resistor R1c and the P-type transistor TPE3 is expressed by Equation (3) below.

$$Ivh = ( VH - Vx ) / R 1 \qquad ( 3 )$$

The current Iref flowing through the P-type transistor TPE2 flows through the N-type transistor TNE1. The N-type transistors TNE1 and TNE2 constitute a current mirror, and the current Iref flows through the N-type transistor TNE2. The inductance current detecting circuit 131 outputs the difference between the current IVh flowing through the P-type transistor TPE3 and the current Iref flowing through the N-type transistor TNE2 as the detected current Isn. Based on Equations (1) to (3) above, the detected current Isn is expressed by Expression (4) below.

$$Isn = Ivh - Iref = ( VH - VSW ) / R 1 = IL \times Ron / R 1 \qquad ( 4 )$$

When the switching device SWT is off, the switch SW1 is on and the switch SW2 is off. The inductor current IL gradually decreases. Since the switch SW1 is on, Iref=Ivh and Isn=0.

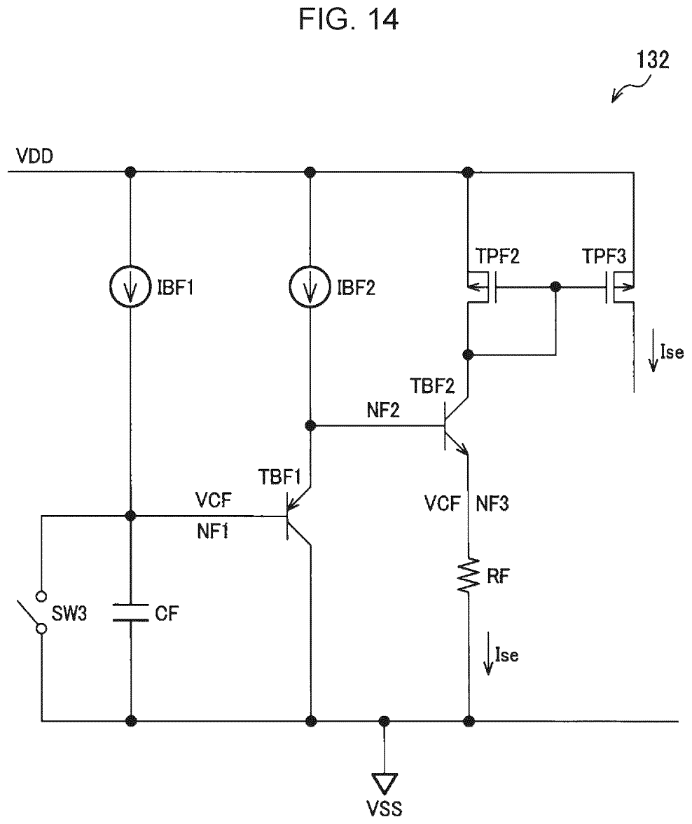

FIG. 14 illustrates an example of a detailed configuration of a slope generating circuit. The internal slope generating circuit 132 includes current source circuits IBF1 and IBF2, a PNP transistor TBF1, an NPN transistor TBF2, P-type transistors TPF2 and TPF3, a switch SW3, a capacitor CF, and a resistor RF. An operation of the internal slope generating circuit 132 will be described below.

When the switching device SWT is on, the switch SW3 is off. When the current source circuit IBF1 causes a current to flow through a node NF1 at one end of the capacitor CF, a voltage VCF at the node NF1 increases at a predetermined rate.

The base of the PNP transistor TBF1 is coupled to the node NF1. It is assumed that a voltage between the base and the emitter of the bipolar transistor is Vbe. In this case, a voltage at a node NF2 of the emitter of the PNP transistor TBF1 is VCF+Vbe. The base of the NPN transistor TBF2 is coupled to the node NF2. A voltage at a node NF3 of the emitter of the NPN transistor is (VCF+Vbe)−Vbe=VCF.

The resistor RF is provided between the node NF3 and the low-potential-side power supply node. When the voltage of the low-potential-side power supply VSS is 0 V, a current VCF/RF flows through the resistor RF. This current VCF/RF flows through the P-type transistor TPF2 and the NPN transistor TBF2. The P-type transistors TPF2 and TPF3 constitute a current mirror, and the current VCF/RF flows through the P-type transistor TPF3. The internal slope generating circuit 132 outputs, as the slope current Ise, a current flowing through the P-type transistor TPF3. That is, the slope current Ise is expressed by Equation (5) below.

$$Ise = VCF / RF \qquad ( 5 )$$

When the switching device SWT is off, the switch SW3 is on. Since both ends of the capacitor CF are short-circuited by the switch SW3, the voltage VCF becomes 0 V. Therefore, Ise=0.

Although the present embodiment is described above, those skilled in the art will readily appreciate that many modifications can be made without materially departing from the features and effects of the present disclosure. Therefore, all such modifications are included in the scope of the present disclosure. For example, a term described together with a different term having a broader meaning or the same meaning at least once in the specification or the drawings can be replaced with the different term in any place in the specification or the drawings. In addition, all combinations of the embodiment and the modifications are also included in the scope of the present disclosure. The configurations, the operations, and the like of the differential amplifier circuit, the phase compensation circuit, the switching signal output circuit, the semiconductor circuit device, the switching regulator, and the like are not limited to those described in the present embodiment and can be variously modified.

What is claimed is:

1. A semiconductor circuit device that is used for a switching regulator that regulates an input voltage using a switching device and an inductor, the semiconductor circuit device comprising:
a differential amplifier circuit that outputs a current based on an output voltage of the switching regulator; and
a switching signal output circuit that outputs a switching signal for the switching device based on a voltage at an output node of the differential amplifier circuit and a voltage corresponding to an inductor current flowing through the inductor, wherein
the differential amplifier circuit includes
a first output-stage transistor that is provided between a first power supply node and a first node and outputs the current, and
a second output-stage transistor that is provided between the first node and the output node and has a gate to which a first bias voltage is input.

2. The semiconductor circuit device according to claim 1, wherein
the differential amplifier circuit includes
a first differential pair transistor having a gate to which a voltage based on the output voltage of the switching regulator is input,
a second differential pair transistor having a gate to which a reference voltage is input, and
a current mirror circuit that mirrors a current flowing through one of the first differential pair transistor and the second differential pair transistor as a current flowing through the first output-stage transistor.

3. The semiconductor circuit device according to claim 1, wherein
the differential amplifier circuit includes
a third output-stage transistor that is provided between a second node and a second power supply node at a potential different from a potential of the first power supply node and outputs the current, and
a fourth output-stage transistor that is provided between the second node and the output node and has a gate to which a second bias voltage is input.

4. The semiconductor circuit device according to claim 3, wherein
the differential amplifier circuit includes
a first differential pair transistor having a gate to which a voltage based on the output voltage of the switching regulator is input,
a second differential pair transistor having a gate to which a reference voltage is input,
a first current mirror circuit that mirrors a current flowing through one of the first differential pair transistor and the second differential pair transistor as a current flowing through the first output-stage transistor, and
a second current mirror circuit that mirrors a current flowing through the other of the first differential pair transistor and the second differential pair transistor as a current flowing through the third output-stage transistor.

5. The semiconductor circuit device according to claim 1, wherein
the first output-stage transistor and the second output-stage transistor are MOS transistors, and
a size of the second output-stage transistor is identical to a size of the first output-stage transistor.

6. The semiconductor circuit device according to claim 3, wherein
the first power supply node is a low-potential-side power supply node,
the second power supply node is a high-potential-side power supply node,
the first output-stage transistor and the second output-stage transistor are N-type MOS transistors, and
the third output-stage transistor and the fourth output-stage transistor are P-type MOS transistors.

7. The semiconductor circuit device according to claim 1, wherein
output impedance of the first output-stage transistor and the second output-stage transistor is 1 MΩ or greater.

8. The semiconductor circuit device according to claim 3, wherein
output impedance of the first to fourth output-stage transistors is 1 MΩ or greater.

9. The semiconductor circuit device according to claim 1, further comprising
a control circuit, wherein
the differential amplifier circuit includes a first switch coupled in parallel to the second output-stage transistor, and
the control circuit controls the first switch such that the first switch is turned on or off.

10. The semiconductor circuit device according to claim 3, further comprising
a control circuit, wherein
the differential amplifier circuit includes
a first switch coupled in parallel to the second output-stage transistor and
a second switch coupled in parallel to the fourth output-stage transistor, and
the control circuit controls the first switch and the second switch such that the first switch and the second switch are turned on or off.

11. The semiconductor circuit device according to claim 1, further comprising
a phase compensation circuit coupled to the output node of the differential amplifier circuit, wherein
the phase compensation circuit includes a resistor and a first capacitor that are coupled in series between the output node of the differential amplifier circuit and a low-potential-side power supply node.

12. A switching regulator comprising:
the semiconductor circuit device according to claim 1; and
the inductor.
